(19) United States
(12) Patent Application Publication
(10) Pub. No.: US 2012/0280284 A1
(43) Pub. Date: Nov. 8, 2012

(54) MICRO-FLUIDIC ELECTRONIC DEVICES AND METHOD FOR PRODUCING SUCH DEVICES

(75) Inventors: I Putu Mahendra Wijaya, Singapore (SG); Isabel Rodriguez, Singapore (SG); Subodh G. Mhaisalkar, Singapore (SG); Wee Yang Ng, Singapore (SG)

(73) Assignee: AGENCY FOR SCIENCE, TECHNOLOGY AND RESEARCH, Singapore (SG)

(21) Appl. No.: 13/440,373

(22) Filed: Apr. 5, 2012

Related U.S. Application Data
(60) Provisional application No. 61/473,534, filed on Apr. 8, 2011.

(51) Int. Cl. G01N 27/414; H01L 21/20; B82Y 15/00; B82Y 40/00

(52) U.S. Cl. 257/253; 438/49; 977/958; 977/888; 257/E21.09; 257/E29.242

(57) ABSTRACT

A micro-fluidic electronic device includes a micro-fluidic component and an electronic component formed on a sheet of paper. An electrically-active layer of the electronic component, such as a nano-material layer, interacts with a fluid sample deposited within a fluid reservoir of the component, and changes the electronic properties of the electronic component. This can be detected by passing an electrical signal through the electronic component. The micro-fluidic electronic device can be formed straightforwardly and inexpensively by printing or mold-casting.

### FIELD OF INVENTION

The present invention relates to the fabrication and application of a micro-fluidic-electronic device, i.e. a device comprising at least one micro-fluidic component for receiving and interacting with a small fluid sample, and at least one electronic component whereby the interaction with the sample changes the electronic properties of the micro-fluidic electronic device. The invention further relates to the fabrication and application of an electronic circuitry integrated with at least one micro-fluidic component.

### BACKGROUND OF INVENTION

The sensing and detection of biomolecules in real-time is important in many medical diagnostic and environmental applications. In contrast to optical sensors, electronic biomolecular sensors offer the advantage of fast response and typically do not require modification of the biomolecules such as labeling with fluorescent markers. The device components are simple and compact in size and easy to integrate in more complex lab-on-chip devices.

Advances in the development of nanotubes/nanowire based transistor have opened a new path for label-free and real-time electronic detection of biological or chemical molecules in aqueous media with improved sensitivity over traditional electronic sensing methods. In one example, it is known to provide liquid-gated field-effect transistors (LGFET) on substrates of a plastics material, such as poly-(dimethyl siloxane) (PDMS). A known PDMS-based LGFET is illustrated in FIG. 1 (a) and consists of two PDMS slabs 1, 2 laminated together to form a functional device. A micro-channel 3 is engraved inside the top PDMS slab 2. A transducing element 4 comprising nanotubes/nanowires, such as a rectangular area of high-density SWCNT (single-walled carbon nanotube) material, is deposited on the lower PDMS slab 1. Electrodes 5 connect wires 6 to the SWCNT area 4. The liquid sample in this device architecture is introduced to the SWCNT film through the micro-channel 3. A pattern of low-density SWCNT 7 is provided covering a gap between the two high density SWCNT area 4 beneath the micro-channel 3, forming a semiconducting transistor channel. The word “density” is used here referring to the number per unit area of SWCNT within the film deposited on the surface.

However, a key feature needed in diagnostics is the availability of inexpensive and disposable sensors.

### SUMMARY OF INVENTION

The present invention aims to provide new and useful microfluidic-electronic devices, as well as methods for producing the devices and methods for using the devices.

In general terms, the invention proposes forming at least one micro-fluidic electronic device on a substrate which is substantially formed on a sheet of paper. The micro-fluidic electronic device includes a micro-fluidic component and an electronic component, having an electrically-active layer. The electrically-active layer of the micro-fluidic electronic device interacts with a fluid sample deposited within a fluid reservoir of the microfluidic component, and thereby changes the electronic properties of the electronic component, and this can be detected by passing an electrical signal through the microfluidic-electronic device, and detecting the signal transmission properties of the electronic component.

The term “paper” is given a conventional meaning. The sheet of paper may optionally have at least one coating layer (e.g. a hydrophobic coating layer), but the aforementioned layer relies for its structural integrity on paper material. The term “paper material” is also used in this document in the conventional sense: a substance formed by pressing together cellulosic materials or starch based materials, typically in the presence of an inorganic fillers such as calcium carbonate, clay, or titanium oxide. The sheet of paper may be laminated from multiple paper material layers.

The term “microfluidic component” is used to refer to a component which is able to manipulate fluids by means of a fluidic channel or conductive contacts with dimensions in the micro range. The volume of the sample is typically measured in nanoliters or pico-liters.

The term “electronic component” is used to refer to a component which is able to make electrical connection and or manipulate charge.

The electrically-active material may be a “nano-material”, i.e. one comprising nanotubes, nanowires, grapheme, or fullerene, or it may comprise organic/inorganic semiconductor thin films. At least one of the layers may be a semi-conductor, while at least one other of the layers may be metallic in nature.

In one possibility, at least one component, either the microfluidic component (e.g. the material defining the fluid reservoir) and/or the electronic component (e.g. the electrically-active material) may be deposited on the paper by printing. Thus, the invention may take advantage of well developed printing technology on paper to construct micro-fluidic electronic devices at low cost. Printing techniques can include inkjet printing, screen printing etc, allowing for large scale fabrication. Previously, printing solution processing has been employed to deposit various nanomaterials, such as carbon nanotubes (CNTs), nanowires, graphene etc to construct electronic devices, but these devices have made use of multiple different materials to achieve the required function. Hence, the fabrication process is more complicated and lengthy. In the present invention the one or more electrically-active layers are preferably formed of a single material. If this material is printed on to the paper, it is possible to provide high throughput and highly inexpensive production of paper-based electronic components.

In another possibility, some or all components of the micro-fluidic electronic device may be formed by a mold casting method, i.e. preparing a mold which is located on the paper, and filling cavities of the mold with one or more liquids which dry to form the components. An advantage of mold casting over prior art methods is that it does not require neither complex and expensive instrumentation, nor highly skilled personnel, so it can be adopted for small-scale production.

Either of these two methods can be up-scaled to attain economies of scale, and hence push down the cost of the devices further. Additionally, the versatility of the fabrication methods offers an interesting potential to create multiple electronic components by printing. This ability to quickly design and print the working prototype of the component has several advantages: (1) it improves the turn-over rate of the designing process, and hence improves its productivity, (2) any defects in the design can be spotted early, and hence can be rectified accordingly at relatively low cost, (3) changes in the design can be incorporated easily, hence adding into the versatility of designs that can be produced.

In either case, the present invention is exemplified in an micro-fluidic electronic hybrid device: a liquid-gated field-effect transistor (LGFET) which can be used for monitoring bioanalytes activities in a liquid sample. The LGFET is an electrical transducer which can detect bioanalytes in liquid sample in real-time and label-free fashion. Very briefly, the LGFET is composed of a transducing element comprising nanotubes and/or nanowires, located between two metallic pads, and encased in a microfluidic reservoir (which may be formed as a microfluidic channel in a solid body, or by a wall encircling the reservoir). A liquid sample is passed over the nanotube/nanowires, and the electrical current is monitored upon the biomolecular interaction. Any bio-events that take place in the proximity of the nanotube/nanowire would then modulate the electrostatic landscape surrounding the nanotube/nanowire, and result in the modulation of the electrical current which can be followed in real-time. The LGFET is able to detect wide-ranging biomolecules open up the path for its application in various sectors, such as the biomedical sector, national security, environment monitoring, etc.

Preferably, the paper substrate carries a plurality of electronic components. These may all be fabricated from a single type of electrically-active material (e.g. nano-material) by spatially modulating the density of nano-material (via the printing and/or mold-casting process). The reduction of the number of materials involved in the construction of the micro-fluidic electronic device and the simplicity of the fabrication method results in lower production cost, and higher production throughput. The ability to create other types of paper-based electronics (e.g. resistors, diodes, and inductors) also offers an advantage in that they can add functionality into the micro-fluidic electronic devices, especially in sensing which may work based on different principle. This ability would enable more types of information to be collected from the sample. Such multi-dimensionality could improve our understanding of a sample, access information which is hard to obtain by using only one type of measurement, or simply add to the arsenal of detection methods which can be selected according to the requirement of a specific sample or experimentation. Finally, these paper-based electronic/fluidic devices could open the path to integrate and interface a microfluidic device with an electronic device such as an integrated circuit, which itself can be printed on the paper substrate.

The proposed method may include steps to alter at least one property of the nano-material. These modification processes allow tailoring of the surface properties and/or the bulk properties of the corresponding nano-material, as required by different situations. The modification of the property of the nano-material may use plasma, photo, mechanical, or chemical treatment. It may for example include density modification in which the electrically-active material is made more or less concentrated, such as by multiple steps of spraying, dipping, transfer printing electro-deposition, electrophoresis, or screen printing. Furthermore, the density or thickness of the electrically-active material may be altered in at least one location (for instance, if the micro-fluidic electronic device is an LGFET, in the channel region) by rubbing, scratching, scotch tape transfer technique or any other relevant technique that is effective in material removal and hence density alteration.

Alternatively, the electronic property modulation may be brought about by chemical means which may include plasma exposure, exposure to gaseous media, chemicals coatings, heat or light exposure. These treatment may be employ hard or soft masking methodologies which may use metal masks, screens, photoresists, PDMS or other polymer based masks or writing methods that may include laser writing, inkjet printing, spray deposition, etc.

Furthermore, the electronic property modulation may be brought about by means of addition of a second phase of electrically-active material, either conductive or semiconductive. For example, metallic nanoparticles or nanowires may be added to a semi-conductor material comprising carbon nanotubes.

Furthermore, it will be important to functionalise the electronic component to be sensitive to particular biomolecules. For example, in the case of an LG-FET the electrically-active material is generally functionalized with specific biomolecules to create a biosensor targeted for the detection of a specific analyte.

Note that this is not the first time that the formation of circuitry on paper has been proposed. For example, M. Dragoman, E. Flahaut, D. Dragoman, M Al Ahmad and R. Plana, “Writing simple RF electronic devices on paper with carbon nanotube ink” (Nanotechnology, Volume 20, 375203, 2009) proposed printing electronic components onto paper. However, the components proposed in that paper are principally for a radio device, and the circuit proposed in that paper is intended to be used in a wholly dry application. These authors did not describe the integration of fluidic and electronic components.

### BRIEF DESCRIPTION OF THE DRAWINGS

Embodiments of the invention will now be described for the sake of example only with reference to the following figures, in which:

FIG. 1(a) shows a known micro-fluidic electronic device formed on two polymer layers laminated together;

FIG. 1 (b) shows an embodiment of the invention which is a paper-based micro-fluidic electronic device, specifically a paper-based LGFET;

FIG. 2(a) shows a paper-based diode which can be incorporated into the same device as the embodiment of FIG. 1(b);

FIG. 2 (b) shows a set of paper-based diodes which may be connected in series in a circuit comprising the embodiment of FIG. 1(b);

FIG. 3 (a) shows a paper-based inductor;

FIG. 3 (b) shows a paper-based resistor;

FIG. 4 (a) shows a measurement set up for characterizing a LGFET, such as the embodiment of FIG. 1(b);

FIG. 4 (b) shows a measurement set up for characterizing a diode, such as the diode of FIG. 2(a);

FIG. 5 (a) is a I_{DS}-VG plot obtained by measuring the paper-based LGFET of FIG. 1(b) using the device of FIG. 4(a);

FIG. 5 (b) is a I-V plot obtained by measuring the paper-based diode of FIG. 2(a);

FIG. 6 shows a measurement configuration for characterizing paper-based inductors, such as the one shown in FIG. 3(a), and resistors, such as the one shown in FIG. 3(b);

FIG. 7 (a) illustrates various paper-based components prepared by using printing method;

FIG. 7 (b) illustrates the formation of various paper-based components prepared by using mold-casting method;

FIG. 8(a) shows experimental data of the kinetic response of the embodiment of FIG. 1(b) upon addition of bioanalytes;

FIG. 8 (b) shows experimental data of the kinetic response of the embodiment of FIG. 1(b) upon addition of the bioanalytes of five different concentrations;

FIG. 8(c) is a calibration plot from triplicate measurements in the experiment of FIGS. 8(b);

FIG. 9 (a) is a schematic diagram of an RL circuit produced on a paper substrate; and

FIG. 9 (b) is a schematic diagram of an amplifier circuit produced on a paper substrate.

### DETAILED DESCRIPTION OF THE EMBODIMENTS

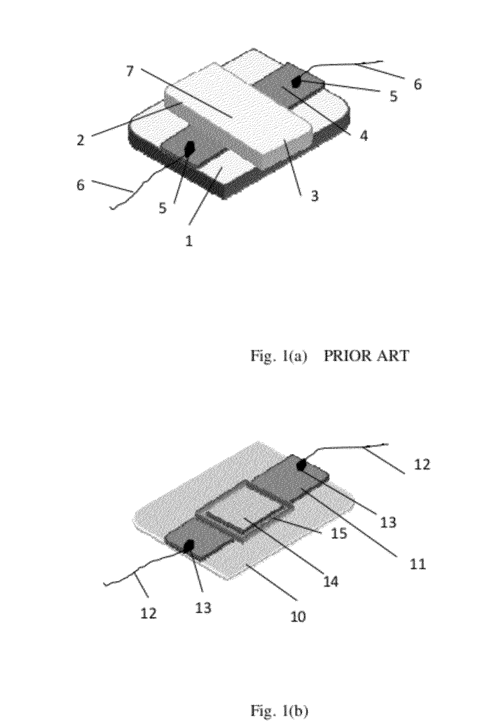

First we will describe an embodiment of the present invention which is shown in FIG. 1(b). This is a micro-fluidic electronic device, in fact a liquid-gated field-effect transistor (LGFET), which includes a micro-fluidic component, and a electronic component, both formed on a paper substrate. The electronic component is adapted to electrically interact with a microfluidic liquid sample. The electronic component may be part of a circuit comprising other components formed on the substrate which may or may not be adapted for contact with, or interaction with the microfluidic sample. After discussing the device of FIG. 1(b), we will discuss more generally methods for the formation of components on a paper substrate.

The paper-based LGFET (FIG. 1 (b)) is formed on a sheet of paper 10. On this sheet is formed firstly a pattern 11 with high content of SWCNT, illustrated as a rectangular strip. Respective ends of the high density SWCNT strip 11 are connected to wires 12 at points 13. A portion in the middle of the high density SWCNT strip 11 is covered by a layer of low density SWCNT 14. This low density SWCNT is surrounded by a rectangular wall 15 which defines a fluidic reservoir. The wall 15 is formed of a polymeric material such as acrylic paint, and is for receiving the microfluidic sample to analyze. As compared to the prior art device of FIG. 1(a), the embodiment of FIG. 1(b) has a simpler architecture, and all the parts of the embodiment are fabricated on the paper. The simple device architecture results in an easier fabrication process, which is described in more detail below.

Another advantage of the paper-based LGFET is the ubiquity of paper itself. Paper is a common material which is used extensively in our everyday lives for many purposes. Paper and acrylic paint are commodities which can be obtained easily and inexpensively off-the-shelf. Additionally, the SWCNT film and the reservoir structure can both be patterned easily through printing and/or a mold-casting method. These methods can be up-scaled for mass-production and attaining economies of scale. These factors give paper-based LGFET a cost-leadership advantage as compared to a PDMS-based LGFET or other biosensing methods.

A PDMS-based LGFET and a paper-based LGFET are similar in that the SWCNT films are patterned to introduce metallic and semiconducting regions in a desired configuration. This pattern creates the required Schottky transistor architecture. Different types of patterns create other types of component, such as diodes, inductors, and resistors, as explained below. An entire family of components can be fabricated from a single nanomaterial, simply by printing and/or mold-casting specific patterns on a paper substrate, so that the corresponding nanomaterial exhibits a spatially modulated density on the paper substrate. An electronic circuit may combine one or more such components and may be combined with one or more micro-fluidic components to form a integrated microfluidic-electronic device according to the invention.

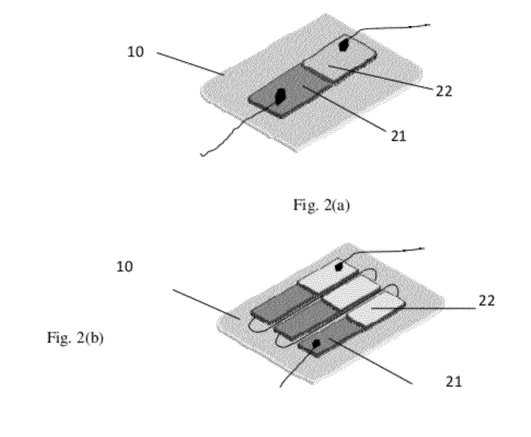

For example, a Schottky transistor can be regarded as two Schottky diode structures connected back-to-back. Thus, a Schottky diode can be produced using the same principles used for creating the LGFET of FIG. 1(b), but by fabricating only half of the structure: dense metallic SWCNT film interfaced with sparse semiconducting SWCNT film. FIG. 2 (a) shows a paper-based SWCNT diode with single interface. A metallic dense SWCNT film 21 is partially covered by a sparse semiconducting SWCNT film 22. Each of the films 21, 22 is connected to respective wires. When a metal is in contact with a semiconductor, a Schottky barrier is created which introduces directionality in the passage of the charge carriers, hence a Schottky barrier is created at the interface of the films 21, 22. Thus, the component of FIG. 2(a) functions as a diode, which can rectify the electrical current passing through it. A cascade of these Schottky barriers can be created by creating multiple diodes of the type shown in FIG. 2(a) in series, as shown in FIG. 2(b) which shows three of the diodes. In effect, the series of Schottky barriers would tackle any stray current from the previous interface, and hence would promote the rectifying behavior further.

A micro-fluidic electronic device which is another embodiment of the invention could be produced by forming a wall surrounding the diode of FIG. 2(a) to function as a reservoir. This would create a fluidic sensor which works based on a diode principle, instead of the transistor principle of FIG. 1(b).

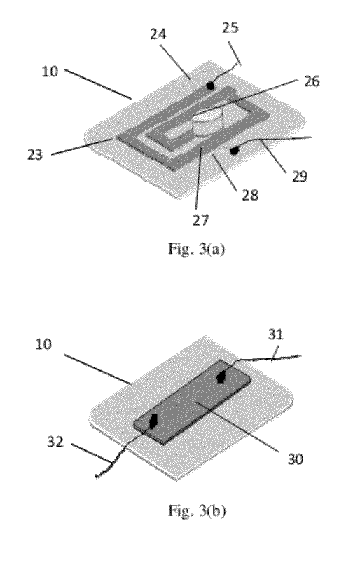

Furthermore, other patterns of SWCNT film may also be printed on the paper to create various other electronic components. The fabrication of these other components is possible because these patterns introduce specific spatial modulation of the nanomaterial density on the paper substrate, which translates into regions in which either the semiconducting or metallic property predominates. Shown in FIG. 3 (a) is a paper-based SWCNT inductor. A coiled pattern of high density SWCNT 23 is formed on the paper 10. One end of the coil 23 is connected at a point 24 to a wire 25 which connects the component to the outside. A magnetic bar 26 is formed at the other end of the core. An electrical connection 27 at the backside of the paper connects the magnetic bar 26 to a point 28 where a connection is made to another wire 29. When a voltage is applied between the wires 25, 29, the coil 23 generates a magnetic field and the direction of the magnetic field is transverse to the plane of the paper 10. The magnetic bar 26 promotes the strength of the magnetic field even further, and hence adds to the inductance of the component.

Furthermore, a resistor can also be made with this printing technique, as shown by FIG. 3(b), by creating of a block 30 of SWCNT film of uniform high-density, connected at its respective ends to wires 31, 32. The block 30 is formed by printing using SWCNT ink, and the magnitude of the resistance can be modulated by controlling the concentration of the SWCNT ink.

Optionally, the electronic components of FIGS. 3(a) and 3(b) may be integrated with microfluidic functionalities which are respective further embodiments of the invention, by providing a fluidic reservoir surrounding some or all of the upper surface of the high-density SWCNT 23, 30 to contain a liquid sample. These embodiments function as further fluidic sensors that work based on inductance and resistance respectively.

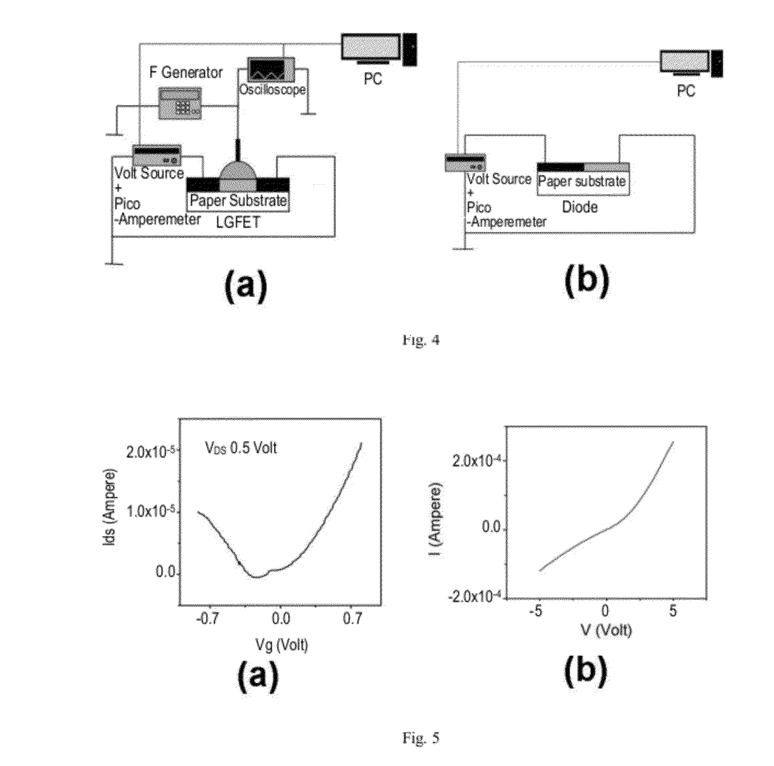

We now present techniques for characterizing electronic components formed on a paper substrate, and results from these techniques. A measurement set up for characterizing the paper-based transistor is shown in FIG. 4(a). The LGFET is a three-terminal set up in which each terminal is connected to a gate, a source and a drain. Important parameter include the gate voltage (V_{G}), source-drain voltage (V_{DS}), and source-drain current (I_{DS}). The transistor action is characterized by modulating the V_{G} while monitoring the I_{DS} at a fixed V_{DS} level. The characterization performed is a measurement of source-drain current (I_{DS}) as a function of gate bias (V_{G}). In this measurement, the source-drain bias (V_{DS}) is applied at the source-drain electrodes at a constant level, while the V_{G} is modulated in a pre-defined window, and the I_{DS} is monitored as a response. FIG. 5(a) shows results obtained by testing the device of FIG. 1(b) using a liquid sample with no dissolved molecules, and demonstrates that the paper-based LGFET exhibits an ambi-polar behavior. This ambi-polar behavior indicates that there are two types of charge-carriers actively involved in the conduction process: electrons and holes. The electrons typically participate in the conduction process when the V_{G} bias is positive, while the holes are predominant when the V_{G} bias is negative. This ambi-polar behavior has previously been reported in PDMS LGFETs, which indicates that the paper-based LGFET still can perform its transistor action properly, even on a paper substrate.

The characterization of diode, however, is quite different from the characterization of the transistor (FIG. 4 (b)). The diode, being a two-terminal component, is connected to a voltage source/pico-ampere meter. A voltage is modulated across the diode, and the current response is monitored. The characterization of diode is performed by modulating the bias applied across the diode architecture, while monitoring the current. FIG. 5(b) shows the resulting I-V plot for a paper-based diode of the kind shown in FIG. 2(a). The conductivity (slope of the I-V curve) is larger in the positive than in the negative bias regime. The difference conductivity indicates directionality in the passage of the charge carrier through the diode. In this case, the carriers conduct more easily when a positive bias is applied than when a negative bias is applied. This preference over direction, is the basis of the functionality of paper-based diode. Ideally, no current would exist in the negative bias regime, but in fact such stray current is still displayed, even when multiple Schottky interfaces are provided. The existence of such stray current may be due to the presence of a metallic nanotube network in the diode structure. One way to reduce this stray current is by creating bare stripe patterns into the semiconducting region of the device. That is, the film 22 will be patterned (e.g. by removing portions of the film 22) as multiple parallel strips, having their length direction parallel to the long direction of the rectangle 21. These strips reduce the interconnectedness of the metallic path, and hence reduce the propensity of the charge carriers to pass through those metallic regions. The introduction of strips in the semiconducting region is one example of mechanical treatment which can be performed to improve the behavior of the component.

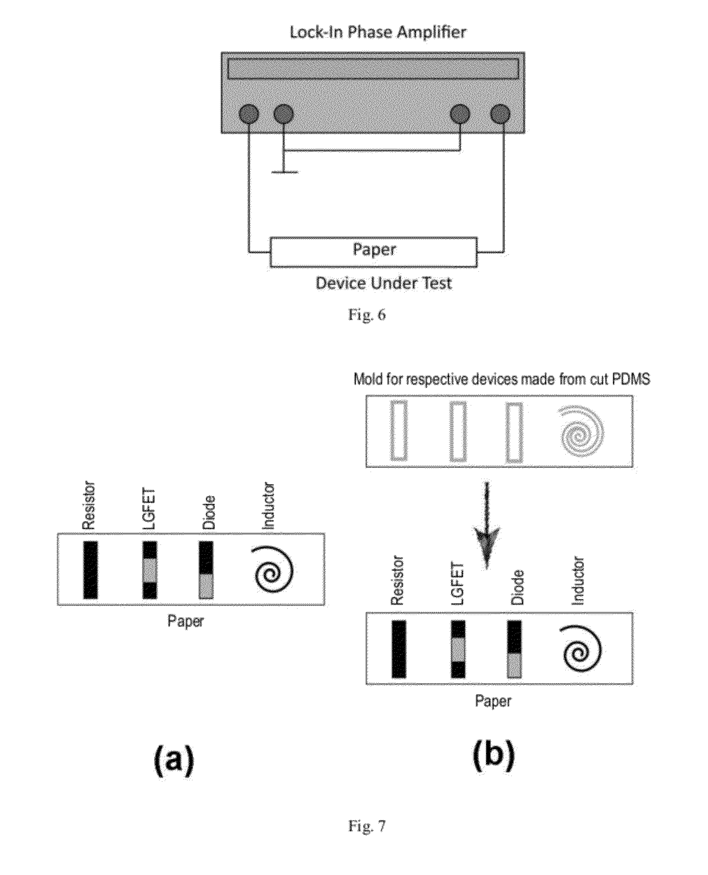

The paper-based inductor of FIG. 3(a) and resistor of FIG. 3(b) are tested using a different measurement configuration, as shown in FIG. 6. Here, the component (device under test, DUT) is connected to a Lock-In Phase Amplifier, and an alternating voltage of fixed frequency is applied across the DUT and the phase is monitored. If the DUT is inductive, it displays a leading phase in the Lock-In Phase Amplifier, whereas if the DUT is resistive, it would display zero phase. The resistance and inductance value of the device then can be back calculated according to the following equations:

R=Z_{magnitude} cos(θ)

ωL=Z_{magnitude} sin(θ) (1)

In one experiment, a paper-based CNT resistor and inductor were tested using a lock-in phase amplifier (Signal Recovery 7265) by applying an AC bias 0.5 V_{RMS} with frequency 10,000 Hz and measuring the resultant current and phase angle.

| | Current Amplitude (μA) | Phase Angle (degree) |
|---|---|---|
| CNT paper resistor | 2.135 | −0.6 |
| CNT paper inductor | 2.133 | −35.68 |

The current amplitude for both components is about the same, indicating that the CNT paper-based resistor and inductor exhibit similar impedance. The inductive nature of the inductor, however, is made clear by the measured phase angle, which is close to zero for the case of CNT paper-based resistor, and about −35° for a CNT paper-based inductor.

FIG. 7(a) is a schematic top-view of four components formed on a paper substrate using ink: a resistor, an LGFET, a diode and an inductor. The patterns necessary for the corresponding components are directly written on the paper either manually or by using a printing unit. FIG. 7(b) shows how corresponding components are produced by mold-casting. The upper part of FIG. 7(b) shows a film of PDMS or other polymer which has been engraved to form respective molds for the components. These molds were then pasted on to the paper, and the SWCNT/nanowire solutions were then introduced into the reservoir as defined by the pattern, and then allowed to dry, and the film was removed.

We now turn to a description of the methods to prepare paper-based fluidic/electronic device and to modify the properties of the nanomaterial.

Phosphate buffer (PB) solution of pH 7.4 was first prepared by mixing NaH₂CO₃ and Na₂HCO₃ solution in a pre-determined concentration. The two components were then stirred while the pH was monitored to attain the targeted pH.

Two SWCNT solution of different concentrations were then prepared. First, a concentrated SWCNT solution in a PB buffer was prepared by dissolving 25 mg of powder carboxylated SWCNT into 50 ml of the PB buffer to yield 50 ml of a 0.5 mg/ml SWCNT solution. Sodium Dodecyl Benzene Sulfonate (SDDBS) surfactant (10 v/v %) was then added into the concentrated SWCNT solution to help disperse the nanotubes in the aqueous media. The concentrated SWCNT solution was then sonicated for two hours in a probe sonicator to break up aggregations in the solution, and to improve its dispersion stability. A second SWCNT solution was then prepared by diluting a fraction of the first solution by 100 times.

The paper substrate used to prepare the device functions as a mechanical support. The nanotubes/nanowires must be able to adhere strongly on to the paper substrate, to withstand the washing steps for removing the surfactant from the nanotubes/nanowires. Hence, an appropriate type of paper was selected. In particular, paper which displays a hydrophobic surface property, such as photographic paper, is desirable for preparing the devices, because of its ability to interact well with the nanotubes/nanowires. Alternatively, a laminated, waxed or polymer coated paper may also be used, because these processes alter the surface property of the paper to become hydrophobic as well.

In order to prepare the hybrid devices, there are two general methods which were employed: printing and mold-casting. Different patterns can be introduced on to the paper to produce a corresponding specific component, and the reservoir can also be introduced on to the paper by printing curable polymers, such as acrylic paint, which are liquid at room temperature, but display resistance to water permeability upon cross-linking Acrylic paint is not the only material that can be used to create the reservoir. Other possible polymers which can be used include: epoxy and its derivatives, and groups of polymers from the polyester family.

To prepare the components by using the printing method, the SWCNT solutions were patterned on to the paper either manually or by using a printing machine. Regions of high- and low-density SWCNT/nanowire films were produced on the paper by controlling the positioning of the concentrated and diluted solutions respectively during the printing process. In this printing process, the paper substrate plays an additional role to prevent the SWCNT solution from spreading uncontrollably on the paper surface. This ability is imparted by selecting proper type of paper which displays a hydrophobic surface property. The resolution of the printing method is dictated by the resolution of the printing machine, and by how well the paper surface can prevent the SWCNT/nanowire solution from spreading. Since the two solutions had different SWCNT concentrations, they result in regions of the paper having a different number of SWCNTs per unit area (i.e. different “densities” of SWCNT).

Alternatively, the patterns can also be produced using a mold-casting method. In this case, a groove in the shape of the wall of the reservoir was cut in a pre-defined pattern into a thick film of PDMS or another type of polymer. The polymer film was then pasted on to the paper, and the groove was filled with concentrated and diluted SWCNT solution in their respective places, and allowed to dry. The resolution of mold-casting method is limited by the smallest feature that can be cut into the polymer film. The properties of the nanomaterial patterned film, and/or even the properties of the nanomaterial itself, are selected to meet specific requirements of the eventual devices being produced. The ability to tailor the properties of the nanostructure film and/or the nanomaterial itself is advantageous to fine tune the performance characteristics of the component to meet different requirements in different applications and conditions.

Several methods will be described in this technological disclosure to permit the modification of the nanomaterial patterned film and/or the nanomaterial itself. The first method is mechanical treatment. In this case, patterns in the form of bare thin strips can be introduced into less dense (semiconducting) region of the nanomaterial film (note that the strips may alternatively be formed by printing). The introduction of strips into the semiconducting region cuts the probability the metallic paths existing which span the semiconducting region, and hence improves the semiconducting behavior of the less-dense film. One application in which this technique may be useful is in the LGFET and diode architecture, where interfacing between semiconducting and metallic region is a pre-requisite.

Alternatively, the properties of the nanomaterial itself can be tailored physically and/or chemically. Physically, the properties of the nanomaterial can be altered by using plasma treatment, UV exposure, or a combination of both. In the case of plasma, the nanomaterial can be exposed to plasma of various gas compositions, such as Oxygen, Fluorine, Chlorine, Air, etc, at various power levels. The highly energetic species from the plasma could interact with the nanomaterial, and alter its properties. Alternatively or additionally, a UV treatment can be performed, in which the nanomaterial is exposed to the UV radiation with sufficient power to introduce the alteration to the corresponding nanomaterial.

The properties of the nanomaterial can also be changed chemically, by exposing the nanomaterial to reactive chemical species, such as: radicals, Fluorine, Chlorine, etc, in either the gas or liquid phase to induce a chemical reaction between the species and the nanomaterial to produce the desired alteration.

As mentioned above, electronic circuits including the electronic components described produced by the printing method could be incorporated with a microfluidic electronic sensing device such as an LGFET. The device circuit may be used for data processing for biosensing operations, optionally in combination with other circuitry/components located on the paper. Optionally, substantially all the circuitry is provided on the paper. Furthermore, multiple microfluidic components can be present on the same piece of paper, to create a self contained lab-on-chip device. In the following paragraphs we describe how a paper-based microfluidic electronic device, such as an LGFET, is prepared for a biosensing application.

For the sake of example only, we shall describe here the detection of a herbicide 2,4-dichlorophenoxy acetic acid (2,4-D) with a competitive immunoassay. For this, after the two solutions have dried, the carboxylated SWCNTs were first covalently linked with a bioconjugates of 2,4-D/Bovine Serum Albumin (BSA) with the aid of linker molecule 1-ethyl-3-[3-dimethylaminopropyl]carbodiimide Hydrochloride (EDC) and N-Hydroxysuccinimide (NHS) following a standard protocol. The coupling of EDC and NHS helps to establish an amide bond between the carboxylated SWCNT and the amine groups in the 2,4-D/BSA conjugate. After the bioconjugation, the active electronic layer was then washed thoroughly in a running DI water to cleanse any un-reacted bioconjugates. The un-reacted SWCNT surface was then exposed to a tween-20 (10 vol. % in PB buffer) blocking agent for two hours to prevent non-specific binding. The amphiphilic nature of tween-20 results in its hydrophobic tails being adsorbed on the nanotube surface, while its hydrophilic poly (ethylene glycol) (PEG) units were exposed into the solution. The presence of the PEG brush coating surrounding the nanotubes prevents interfering biomolecules from being adsorbed on to the nanotube surface, and hence minimizes the propensity of non-specific binding. The blocking process can be monitored by following the I_{DS} against time.

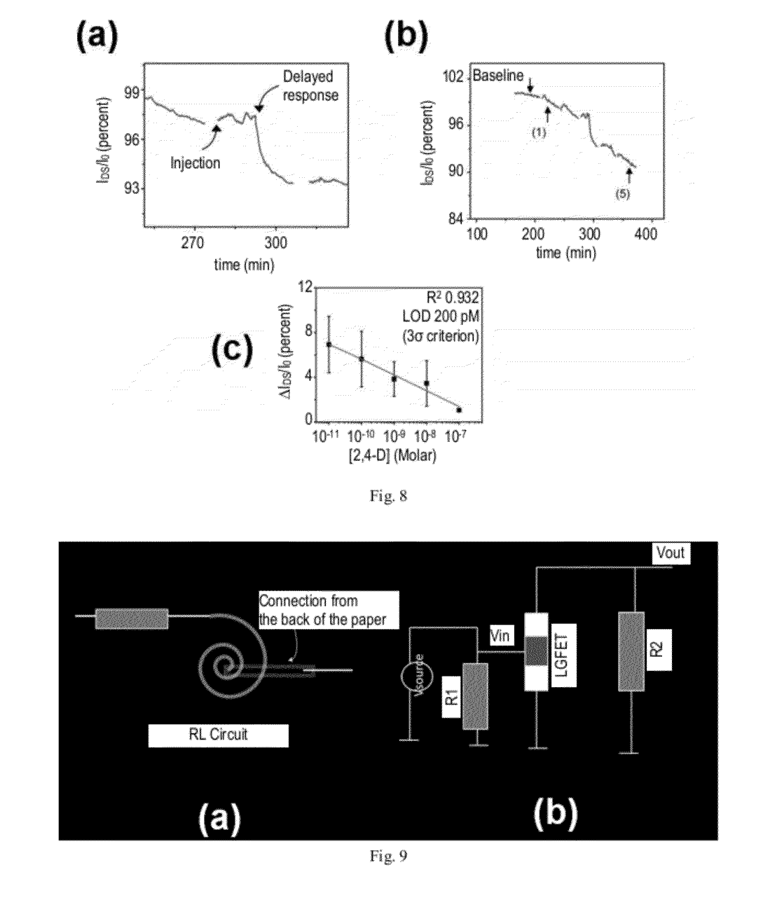

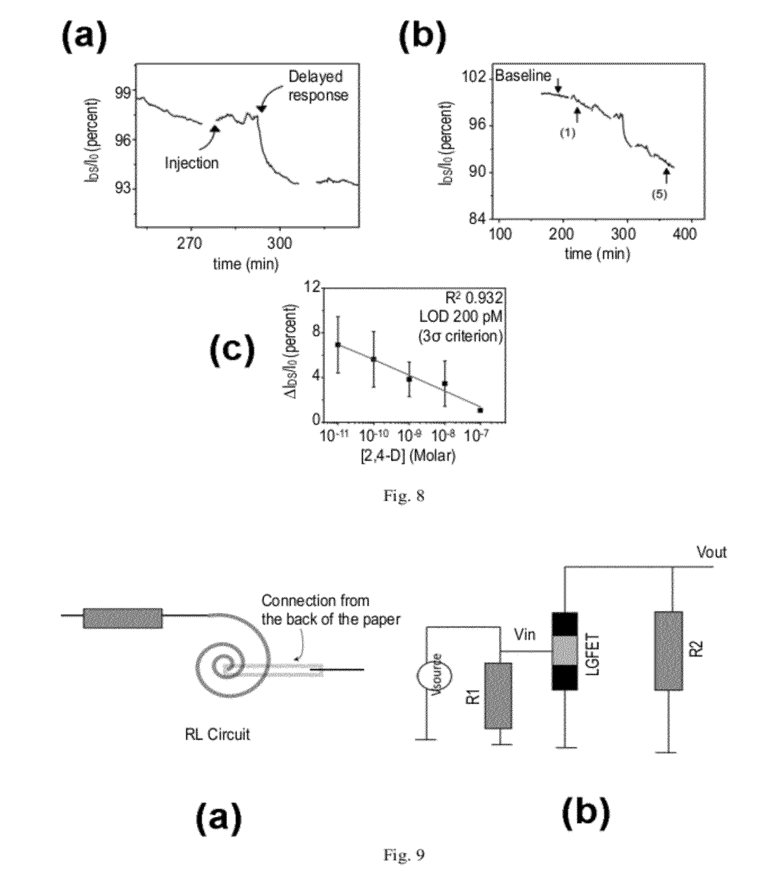

To create a calibration plot (FIG. 8(c)), logarithmic series of 2,4-D solutions in PB buffer were prepared: (1) 100 nM, (2) 10 nM, (3) 1 nM, (4) 100 pM, and (5) 10 pM. Additionally, a solution of antibody of 2,4-D (referred here as anti-(2,4D)) of 100 nM concentration in PB buffer was also prepared. Prior to injection into the LGFET reservoir, the 2,4-D and the anti-(2,4-D) solutions were pre-mixed and let stand for two hours. A known amount of the anti-(2,4D) solution was mixed into each of the five 2,4-D calibration solutions, and the 5 mixtures were allowed to stand for two hours. They were then injected sequentially into the reservoir of the LGFET embodiment of FIG. 2(b) in the order (1) to (5), and subsequently detected.

A baseline I_{DS} was collected in the kinetic measurement at the beginning of each experimentation, using PB buffer of the exact same ionic-strength as the one used for dissolving the biomolecules. Previous experimentations have shown that maintaining this ionic-strength is crucial to avoid false positives due to changes in the ionic-strength of the solution. The competitive immunoassay was then performed by injecting the pre-mixed solution into the reservoir of the paper-based LGFET. In this competitive immunoassay, the free un-reacted 2,4-D in the sample competes with the 2,4-D/BSA bioconjugates to bind with the anti-(2,4-D), and hence the signal level is inversely proportional to the concentration of the target bioanalytes. Three measurements were repeated to ensure the repeatability of the data. The resulting data was then plotted into calibration curve, and fitted according to a logarithmic function with three-parameters:

$$\frac{{I}_{DS}}{{I}_{0}} = a - b log ( [ 2 , 4 - D ] + c ) \qquad ( 2 )$$

The statistical test Analysis of Variance (ANOVA) was then performed to determine the aggregate variance from the regression, taking into account the inter-experiments spread of data. Three times of the standard deviation (3σ) obtained from the ANOVA test was then used as the criterion to calculate the limit of detection, again by using Equation (2). The results obtained from the kinetic measurement are shown in FIGS. 8(a) and (b). Note that the starting point of the horizontal axis (i.e. the time time=0) is chosen arbitrarily. FIG. 8(a) shows the results obtain from using solution (3), and FIG. 8(b) shows the results from all of solutions (1) to (5).

A time delay of approximately 10 minutes is observed between sample injection and the change in the I_{DS}, as shown in FIG. 8(a). This time delay is as expected, and it corresponds to the time taken by the biomolecules to travel across the droplet to the surface of the nanotube film. In FIG. 8(b), it is noted that the I_{DS} drops even further as the number of anti-(2,4-D) molecules in the solution is higher, as the concentration of the target molecule 2,4-D in the sample decreases. The I_{DS} drop indicates that the nanotube surface is exposed to the part of the anti-(2,4-D) molecule which is rich in positive charge.

The corresponding calibration plot obtained from triplicate measurements is shown in FIG. 8(c). Here it is shown that the signal level is inversely proportional to the concentration of the 2,4-D, as expected from competitive immunoassay. The calibration data points were then fitted by using three parameters of the logarithmic function which is Equation (2). The R² calculated during the regression routine is 0.932, which indicates that the equation explains the trend in the underlying data points quite well. The LOD was determined by using 3 σ criterion, yielding a value of approximately 200 pM.

As discussed above, the paper-based circuit can also include passive electronic components. The components can be interconnected to form a functional electronic device to perform other functions within a fluidic based platform. FIGS. 9(a) and (b) show two examples of how the paper-based components can be inter-connected to form a functional electronic circuit. FIG. 9(a) shows a simple RL circuit which can function as either as a low-pass or high-pass filter, depending on the exact configuration of the circuit. Cascading a high-pass and low-pass filter together can also produce a band-pass filter, and a receiving antenna to capture an electromagnetic wave. In the later case, the value of the R and the L needs to be tuned so that the resonant frequency of the RL circuit exactly matches the frequency of the electromagnetic wave that would like to be harvested.

Another example is an amplifier circuit, as one shown in FIG. 9(b). Here, the Vᵢₙ, functions as the V_{G}, and hence controls the I_{DS} that passes through the LGFET. Thus, modulation at the Vᵢₙ is transferred to the I_{DS} which then controls the Vₒᵤₜ with the aid of R2. If we select the parameters of the components in such a way that R2>>R1, the Vₒᵤₜ is greater than Vᵢₙ; in other words, the Vin has been amplified.

1. A microfluidic electronic device comprising a sheet of paper and at least one microfluidic component and at least one electronic component mounted on the sheet of paper;
the at least one microfluidic component comprising
a fluid reservoir;
the at least one electronic component comprising:
at least one layer of electrically-active material for interacting with a liquid sample located in the fluid reservoir; and
electronic connections to transmit an electric signal through the layer of electrically-active material,
whereby interaction between the electrically-active material and the liquid sample modifies the transmission of the electric signal through the electrically-active material.

2. The microfluidic electronic device of claim 1 in which the electrically-active material comprises at least one of nanotubes, nanowires, graphene, fullerene, organic semiconductor thin films or inorganic thin films.

3. The micro-fluidic electronic device of claim 1 in which there are a plurality of said layers of electrically-active material, with different electronic properties.

4. The micro-fluidic electronic device of claim 1 in which the at least one electrically-active layer comprises regions having the same constituents in different respective proportions.

5. The micro-fluidic electronic device of claim 1 in which the at least one layer of electrically-active material comprises a semiconductor layer and a metallic layer.

6. The micro-fluidic electronic device of claim 1 in which the at least one layer of electrically-active material is formed into a coil.

7. The micro-fluidic electronic device of claim 6 in which the micro-fluidic electronic device further comprises a body of magnetic material.

8. The micro-fluidic electronic device of claim 1 in which the at least one layer of electrically-active material comprises a plurality of strips of material spaced apart parallel to the surface of the paper.

8. The micro-fluidic electronic device of claim 1 further comprising an amplifier circuit formed on said paper.

9. The micro-fluidic electronic device of claim 1 in which the at least one layer of electrically-active material includes constituents to enhance interaction with specific biomolecules in the liquid sample.

10. The microfluidic electronic device of claim 1 including a plurality of said electronic components, wherein for different ones of said electronic components the respective at least one layer of electrically-active material is adapted to interact to different degrees with different respective biomolecules.

11. The microfluidic electronic device of claim 1 in which the at least one micro-fluidic component is formed on a surface of the paper having a hydrophobic coating.

12. The microfluidic electronic device of claim 1 in which the at least one micro-fluidic component is a liquid-gated field effect transistor.

13. A method for forming a microfluidic electronic device comprising a sheet of paper, at least one microfluidic component and at least one electronic component mounted on the sheet of paper, the method comprising forming the at least one microfluidic electronic device by:
forming said at least one electronic component by depositing onto a sheet of paper at least one layer of electrically-active material;
forming said at least one micro-fluidic component by defining a fluid reservoir, the fluid reservoir being located to permit interaction between the at least one layer of electrically-active material and a liquid sample located in the fluid reservoir; and
forming electronic connections operative to transmit an electric signal through the layer of electrically-active material.

14. The method of claim 13 further comprising modifying at least one property of said at least one layer of electrically-active material by a step of physical processing.

15. The method of claim 14 in which said step of physical processing comprises mechanical processing, or exposing the at least one layer of electrically-active material to plasma or UV radiation.

16. The method of claim 13 further comprising modifying at least one property of said at least one layer of electrically-active material by a step of chemical processing.

17. The method of claim 16 in which said step of chemical processing comprises exposure of said at least one layer of electrically-active material to reactive chemical species in the gas or liquid phase.

18. The method of claim 13 further comprising a step of sensitizing the at least one layer of electrically-active material to a specific biomolecule.

19. The method of claim 13 in which a plurality of said electronic components are formed, the method including a step of sensitizing the at least one electrically-active layer of multiple said electronic components to different respective biomolecules.
